(19) United States
(12) Patent Application Publication
(10) Pub. No.: US 2006/0157703 A1
(43) Pub. Date: Jul. 20, 2006

(54) Charged plate,CDM simulator and test method

(75) Inventors: Noriyuki Kodama, Kanagawa (JP); Tsuneo Tsukagoshi, Tokyo (JP)

Correspondence Address: SUGHRUE MION, PLLC, 2100 PENNSYLVANIA AVENUE, N.W., SUITE 800, WASHINGTON, DC, 20037, US

(73) Assignees: NEC ELECTRONICS CORPORATION; NEC CORPORATION

(21) Appl. No.: 11/402,042

(22) Filed: Apr. 12, 2006

(30) Foreign Application Priority Data
Apr. 12, 2005 (JP) 2005-114590
Feb. 28, 2006 (JP) 2006-052412

(51) Int. Cl. H01L 23/58

(52) U.S. Cl. 257/48

(57) ABSTRACT

Disclosed is a simulator in which there are provided a field plate for electrostatically charging a device under test, which comprises a first substrate (high resistance substrate) having a relatively high resistance and a substrate having a predetermined dielectric constant; and a ground plate for discharging the charged device which comprises a relatively high resistance member and further comprises an additional ground plate.

### FIELD OF THE INVENTION

The present invention relates to a CDM (charged device model) simulator used in electrostatic discharge test of semiconductor devices and a test method.

### BACKGROUND OF THE INVENTION

With the continuous scaling down of the physical dimensions of transistors in semiconductor integrated circuits (hereinafter abbreviated “IC”), the breakdown voltage in ICs has become lowered. Problems of breakdown in ICs due to electrostatic discharge (hereinafter referred to as “ESD”) have become more serious. Among reliability tests, an ESD test is carried out to test ESD tolerance of IC.

Conventional test methods may include a capacitor discharge test method which simulates discharge from an electrostatically charged human body to an IC. This discharge may occur when an electrostatically charged object is present in the vicinity of an IC. In the test, a human body model (HBM) which simulates the discharge from a charged human body to an IC or a machine model (MM) which is presumed to simulate direct discharge from a charged metallic capacitor body to an IC is used. Countermeasures against electrostatic discharge from charged human body have been widely taken. The wide spread use of automatic fabrication lines for electronic devices reduces the possibility of direct contact between human body and IC. Under this situation, it has been found that existing models for capacitor discharge test are often incapable of reproducing a defective mode in an automatic assembly process.

Seakman et al. proposed in 1974 a model other than HBM, MM models in which an IC may be broken by rapid discharge from a discharged IC. This model is called as “charged device model” (CDM).

This CDM received attention with the development of a CDM simulator for simulating a device charged model as a momentum, which was made by Bossard, Unger et al. during the 1980s (refer to non-Patent Document 1). Thereafter, various CDM simulators have been developed.

These conventional CDM simulators are electrostatic breakdown test instruments which simulates electrostatic discharge in ICs to measure its immunity from the breakdown. These CDM simulators are used for designing ICs so that they have enough immunity from the breakdown due to electrostatic discharge. They are used to make an assessment of performance of ESD protection device or to determine the references for ESD management standards in an assembly process based upon the immunity of the product from the breakdown, or used for shipment test of products.

FIG. 8 is a diagram showing the equivalent circuit of CDM discharge in case of electrostatic charges being accumulated on a device. A characteristic effect in the discharge phenomenon caused by CDM is that electrostatic charges on a device capacitance in IC 10 is discharged instantaneously when they are brought into contact with a metallic body having a low inductance via an in-aerial discharge path. Accordingly, the waveform of the discharge current has features that the rise time of the current is fast (for example, the rise time is as fast as 100 psec) and its peak current is high in amplitude and short in continuing period of time. If the turning on speed is lower like thyristor or bipolar protection element when discharge is fast in such manner, an over-voltage will be applied to an internal circuit. With regard to the placement of the internal circuit, the potentials on circuit blocks become non-uniform, an excessive potential difference may occur between given element portions.

Since some specific marks of structural destruction of the device, in which the destructed portion is turned in to an amorphous state, and which is other than melting of the device due to heating, have been found, it is understood that for example, a gate oxide film is broken for example, by over-voltage, which occurs due to an excessive potential difference among respective portions in an IC. Some analyses report that characteristic actual broken portions are similar or identical with those in CDM test, and CDM simulators have been widely used.

It is presumed that major cause of electrostatic charging of device is induced charging (induced polarization). This can be explained by a mode in which uncharged IC (device) 10 is placed on a charged insulator 201 and discharge occurs when a conductor is brought into contact with an IC 10 as shown in FIG. 9. It is assumed that an internal conductor 12 of the IC 10 is electrically neutral and a package 13 is not electrostatically charged. If the IC 10 is placed on the charged insulator 201, the internal conductor 12 of the IC 10 is electrostatically charged to one polarity due to electrostatic induction. Charges having a polarity (negative charges in the drawing) different from that of the charges on the charged insulator 20 appear on a portion of the internal conductor 12 of the IC 10 which is close to the charged insulator 201. Charges having the same polarity (positive charges in the drawing) as that of the charges of the charged insulator 201 appear on a portion of the internal conductor 12 of the IC 10 which is far from the charged insulator 201. It is explained that the internal conductor 12 of the polarized IC 10 is grounded, charges having a polarity different from that of the charges on the charged insulator 201 (positive charges in the drawing) is discharged to the ground. In other words, when a contact needle (or pogo pin) 501 is abut to a pin 11 of the IC 10, positive electrostatic charges are discharged to the ground.

The amount of induced charges is represented as follows:
Q=−Cpk×V

where Cpk is capacitance between the surface of the package 13 of the IC 10 and the internal conductor 12 of the IC 10 (referred to as “package capacitance”) and V is the voltage at the surface of the insulator (201 in FIG. 9). The amount of charges when discharge occurs is represented as “Q”.

When the IC 10 is moved away from the charged insulator as shown in FIG. 10, after discharge shown in FIG. 9, electrostatic charges having a polarity different from that of the charges on the insulator (201 in FIG. 9) are accumulated on the IC 10. Thus, there is one mode in which discharge may occur when the IC on which charges are accumulated is brought into contact with the metallic object 202 again.

There is another discharge mode in which electrostatic charges on the surface of the package will cause induced charging. This mode will be referred to as “package surface charging mode”.

Specifically, various types of simulator have been proposed as follows:

FIG. 12 is a diagram showing the configuration of a direct-charging charged device model (hereinafter referred to as “D-CDM”). Charging and discharging is conducted via a relay switch 502 by bringing a direct charging and discharging electrode (contact needle) 501 into a terminal 11 of IC 10.

A charged package model (CPM) is configured so that charging is conducted via a electrode made of Bakelite and discharging is conducted by bringing a discharging electrode connected with the ground to a sample to cause in-air discharge (refer to non-Patent Document 2). A case using a small capacitance discharge model (in which a current flows into an IC from an external source) which is similar in apparatus configuration to the charged package model is described in Patent Document 5. The direct charging type apparatus as is described in Patent Document 5 has such problems that variations in the resistance during charging can not be precisely controlled and that a surface leakage current may be generated.

A field induced charged device model (referred to as FI-CDM) is configured so that field induced charging is caused by placing the IC 10 on the field plate insulator 201 within an electric field formed by a field plate 204 connected to a high voltage power supply 301 and a discharging electrode facing thereto to in-air discharge the electrostatic charges (non-Patent Document 3).

In this type of simulator, a contact needle 501 is mounted on a ground plate 504 which forms a uniform electric field between a field plate. The ground plate 504 is lowered simultaneously with lowering of the contact needle 501 to contact with a terminal 11 of IC 10.

Thus, the distance between the field plate 204 which is charged to a predetermined potential and the ground plate 504 is changed. Resultingly, the electric field, electrostatic capacitance and the amount of charges for IC 10 is changed, so that the electric field, electrostatic capacitance and the amount of electrostatic charges is also changed. If there is no ground plate or the area of the ground plate is small, a problem occurs that the distribution of the electric field for IC may become non-uniform and variations in discharge current among test terminals may occur. Hence, a method of forming an electric field between parallel flat plates having a large area has been adopted.

An approach which overcomes disadvantages of existing FI-CDM simulator by eliminating in-air discharge which is one of the disadvantages of FI-CDM is disclosed in Patent Document 1. In this Patent Document 1, an influence of the ground plate 504 is eliminated by using no ground metallic plate which was provided to form an equal electric field between the metallic plate and a field plate which induces electrostatic charges and by preliminarily contacting a contact needle with a terminal 11 of IC 10 placed upon the field plate 204.

A structure which adopts an field plate of a high dielectric constant is disclosed in Patent Document 4. A CDM simulator in which after an IC is placed on a ground face and is directly electrostatically charged with a contact needle, the IC is lifted up to bring the IC into contact with a discharge needle which is above the IC to cause an in-air discharge is described in Patent Document 5.

It is reported in Non patent Document 5 that when the IC is lifted up, the device capacitance (a capacitance for space including a capacitance against the ground plate) decreases, so that the potential correspondingly increases, the peak current becomes higher and the pulse width becomes narrower irrespective of the same total amount of charges. It is explained that this is due to the fact that the current abruptly flows if the potential difference on discharge is large. It is shown in the course of modeling the circuit operation of a CDM tester with an equivalent circuit that the capacitance between the IC and the ground plate gives a large influence upon the waveform of the discharge current, in Non patent Document 8.

Known examples of CDM simulator which is related with device capacitance are described in Patent Document 3 and non-Patent Document 7. In “JEDEC STANDARD JEDS 22-C101, ESDASTANDARD ESD-S 5.3” or Electronic Industries Association of Japan: EIAJ, Temporary Standard E1AJEDX-4702, there is described a method, which comprises measuring the waveforms of the discharge currents for comparing peak values, pulse widths, oscillation periods and dumping time constants of oscillation among test equipments and obtaining correlations among the test equipments, in order to prevent variations in measurement results among test equipments from occurring. In this case, a parallel flat plate capacitor having a predetermined capacitance (4 pF or 30 pF) using a printed circuit board is used as a device under test in lieu of an IC. When a parallel flat plate capacitor of 4 pF is used, discharge current is such that the rise time of the pulse is 200 pF or less and the pulse width is 400 ps or less.

[Patent Document 1]

Japanese Patent Kokai Publication No. JP-P2001-91572A

[Patent Document 2]

Japanese Utility Model Kokai Publication No. JP-U-7-36078

[Patent Document 3]

Japanese Patent Kokai Publication No. JP-P2003-28921A

[Patent Document 4]

Japanese Patent No. 2859044

[Patent Document 5]

Japanese Patent Kokai Publication No. JP-A-7-98355

[Non Patent Document 1]

“ESD DAMAGE FROM TRIBOELECTRICALLY CHARGED IC PIN” P. R. Bossrd, R. G. Chemelli, B. A. Unger; Electrical Overstress/Electrostatic Discharge Symposium Proceedings, EOS—2 Sep. 1980, Pages: 17-22

[Non Patent Document 2]

“ESD PROTECTION NETWORK EVALUATION BY HBM AND CDM (CHARGED PACKAGE METHOD)”, Y. Fukuda, S. Ishiguro, M. Takahara; Electrical Overstress/Electrostatic Discharge Symposium Proceedings, EOS—8 Sep. 1986, pages: 193-199

[Non Patent Document 3]

“Mechanism of Charged-Device Electrostatic Discharges”, Robert G. Renninger; Electrical Overstress/Electrostatic Discharge symposium Proceedings, EOS—13 Sep. 1991, pages: 127-143

[Non Patent Document 4]

“Establishment of device charged model EST test method (part 1) Development of practical precise experiment method”, M. Tanaka, M. Sakimoto, H. Nishimae, K. Ando, RCJ Twelfth EOS/ESD symposium, collection of drafts, pages: 33-40

[Non Patent Document 5]

“Study of electric discharge from micro-device”, H. Hayata, S. Koike, M. Honda, 2004, fourteenth RCJ Reliability Symposium Proceedings 14E-8, pages: 117-122

[Non Patent Document 6]

“Relationship between discharge waveform and discharge resistance in low voltage CDM discharge”, S. Isofuku, 2004, fourteenth RCJ Reliability Symposium Proceedings, 14E-21, pages: 191-196

[Non Patent Document 7]

“INFLUENCE OF TESTER PARASITICS ON “CHARGED DEVICE MODESL”—FAILURE THRESHOLDS”, H. A. Gieser, P. Egger; Electrical Overstress/Electrostatic Discharges Symposium Proceedings, EOS—13 Sep. 1994, pages: 69-84

[Non Patent Document 8]

“Impact of the CDM tester ground plane capacitance on the DUT stress level” Cedric Goeau, Corrine Richier, Pascal Salome, Jean-Piearre Chante, Herve Jaouen: Electrical Overstress/Electrostatic Discharge Symposium Proceedings, EOS—7 Sep. 2005, pages: 170-177

### SUMMARY OF THE DISCLOSURE

CDM discharge phenomenon has a feature that the rise time of the discharge current is very fast and the peak current value is very high. Some ESD protective elements suppress the voltage applied to an element to be protected to a low voltage while other elements can not suppress fast rise-up current to sufficiently low voltage. In latter case, an excessively high voltage may be applied to the element to be protected. As a result of occurrence of an excessively large current over the entire of inner circuit, an excessively high voltage may occur on a predetermined portion. It is presumed that such a phenomenon specific to CDM destruction usually depends upon the peak value and rise time of the discharge current, rather than integrated value of the current. In other words, the risk of breakdown becomes higher as the peak value of the discharge current becomes higher (the rise-up of the current is faster) if charges having same amount are discharged.

Therefore, it is necessary to make it possible to achieve a simulation of worst case, in which a rise time of current as fast as possible is realized, so that the waveform of discharge current which may be actually generated in manufacturing process can be reproduced and a guide line to design of protective circuit can be obtained. There are following problems relating to discharge which is simulated by existing CDM simulator.

A discharge model based upon which FI-CDM is proposed is originated from a model in which a metallic jig (contact probe) 501 is brought into contact with a pin 11 of an IC 10 on charged insulator 201 or a model in which the package surface is electrostatically charged.

FI-CDM simulator (FIG. 13, Non Patent Document 2) which simulates the discharge phenomenon forms the device capacitance (capacitance between field plate and the IC) of a field plate (metallic plate) similarly to D-CDM simulator.

D-CDM simulator is described using an equivalent circuit of a tester in Non Patent Document 8. Also in FI-CDM, the equivalent circuit is capacitance-coupled with a ground electrode via a metallic electrode of field plate as shown in FIG. 18A, so that resonant oscillation in the entire circuit system occurs. In other words, it is concluded that a current flows to a metallic electrode portion of field plate 204 as shown in FIG. 16. The distribution of a discharge current in the IC is considered different from actual current distribution. If there is such an occasion wherein the metallic electrode of the filed plate may serve to bring about uniform potential distribution in the IC, test results obtained by the simulator is rendered less reliable. It is unlikely that such a metallic member is a direct contact with an IC package in an actual discharge. It is needed to implement a CDM tester which is capable of reproducing actual CDM discharge phenomenon as close as possible.

In accordance with one aspect of the present invention, there is provided a simulator apparatus for an electrostatic discharge test may comprise a member for absorbing an electromagnetic wave which is generated when discharge from said device under test occurs. In the present invention, a field plate for electrostatically charging a device under test may comprise a member for absorbing an electromagnetic wave generated at the time of discharge. Alternatively, said reference potential plate may comprise a member for absorbing an electromagnetic wave generated at the time of said discharge.

In the present invention, said field plate may comprise a first substrate as said absorbing member.

In the present invention, said first substrate may have such a resistance value that the substrate absorbs an induced current from said field plate at the time of said discharge.

In the present invention, said field plate may comprise a second substrate having a predetermined dielectric constant, which is disposed on said first substrate on the side thereof on which said device under test is placed and an electrode on the side of said first substrate opposite to the side on which said second substrate is provided.

In the present invention, said second substrate may have a dielectric constant so that the capacitance of the second substrate is more than package capacitance of said device under test.

In the present invention, said first substrate may be made of an insulting substrate and may comprise an electrically conductive area disposed on said insulating substrate, on which said device under test is placed and an electrode which is connected to said electrically conductive area.

In accordance with another aspect of the present invention, there is provided a ground plate on which said device under test is placed and which is connected to the ground may comprise a substrate in the simulator apparatus for electrostatic discharge test of a device under test.

In accordance with another aspect of the present invention, a voltage which does not capacitance-couple with an external environment in a discharge frequency band may be applied when discharge occurs.

In the present invention, a resistor element is in series connected to a switch connected between the ground and a needle connected to a conductor of a device under test as a discharge side path. The resistance value is preset to match the waveform of in-air discharge. The resistance value may be changed as a function of an applied voltage value to match the waveform of the discharge in the voltage range.

In the present invention, the electrode of a relay which forms said switch leads out in three directions in a dimensional structure.

In such a manner, in accordance with the present invention, a field plate is made of a material which is not responsive to the potential oscillation at CDM (device charged model) frequency. The field plate has a high resistance substrate having a sufficient conductivity which absorbs CDM discharge an electromagnetic wave.

The present invention provides a ground plate which is used for discharging charges on a device under test in an electrostatic discharge test. The ground plate may comprise a high resistance member. The ground plate of the present invention may comprise a member for further accumulating the capacitance. Said member for further accumulating the capacitance may comprise an additional ground plate which is disposed on the surface of said ground plate opposite to the surface facing to said sample. Said ground plate may comprise a member for absorbing an electromagnetic wave which are generated at the time of discharge from said device under test. Alternatively, said ground plate may comprise said relatively high resistance member on the surface of said ground plate facing to said device under test.

A simulator apparatus in accordance with yet another aspect of the present invention may include a field plate used in an electrostatic discharge test for electrostaically charging a device under test and a ground plate used for discharging said electrostatically charged device under test. Said ground plate comprises a relatively high resistance member.

A method of conducting an electrostatic discharge test in a further aspect of the present invention may be conducted by using a relatively high resistance member as a field plate for electrostatically charging said device under test and/or a ground plate for discharging said charged device under test.

The meritorious effects of the present invention are summarized as follows.

In accordance with the present invention, a discharge model which has heretofore been difficult can be reproduced by making a field plate of a material which does not respond to the potential oscillation at a CDM (charged device model) frequency.

More specifically, in accordance with the present invention, a phenomenon in which a device under test having a package surface electrostatically charged is made in a contact in such a manner that no capacitance is formed against the contact surface.

In accordance with the present invention, discharge of a device under test which an IC placed on an electrostatically charged object can be reproduced.

In accordance with the present invention, the discharge current waveform can be matched to that in worst case in an environment at which actual breakdown occurs.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing the configuration of the whole of an apparatus of one embodiment of the present invention.

FIG. 2 is a diagram showing the configuration of a modification of a field plate in one embodiment of the present invention.

FIG. 3 is a diagram showing the configuration of a modification of a field plate in one embodiment of the present invention.

FIG. 4 is a diagram showing the configuration of a modification of a field plate in one embodiment of the present invention.

FIG. 5 is a diagram showing the configuration of a modification of a charging substrate in the embodiment of the present invention.

FIG. 6 is a diagram showing another modification of the present invention.

FIGS. 7A and 7B are views showing the configuration of one embodiment of a low inductance relay used in the present invention.

FIG. 8 is a diagram showing the equivalent circuit of prior art CDM discharge model.

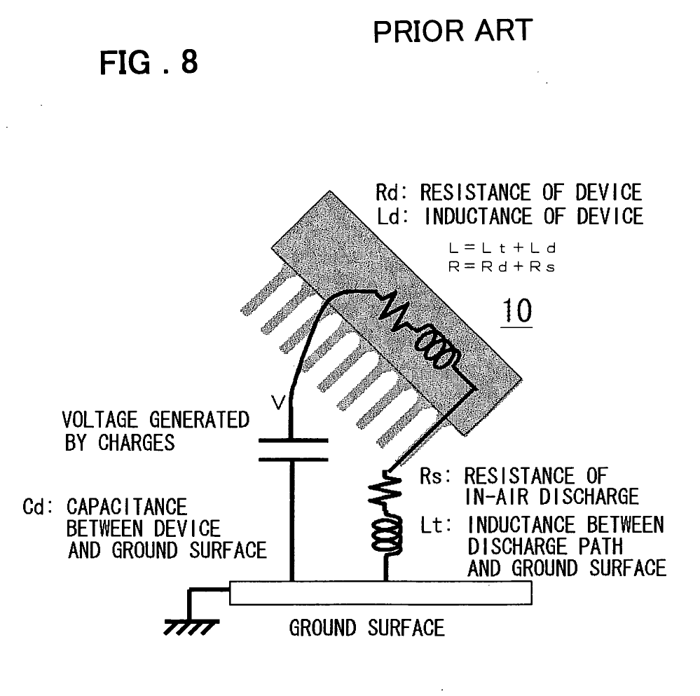

FIG. 9 is a view explaining CDM destruction with a prior art induced charging model.

FIG. 10 is a view explaining CDM destruction with a prior art induced charging mode.

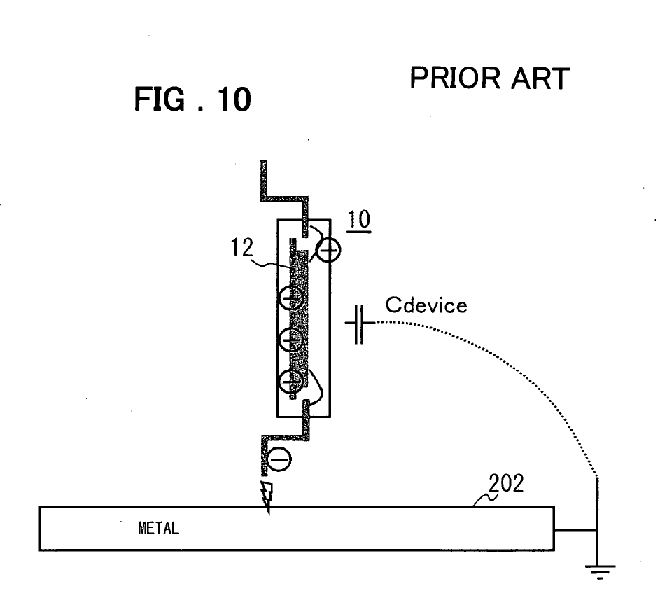

FIG. 11 is a view explaining CDM destruction by the package surface charging in a prior art.

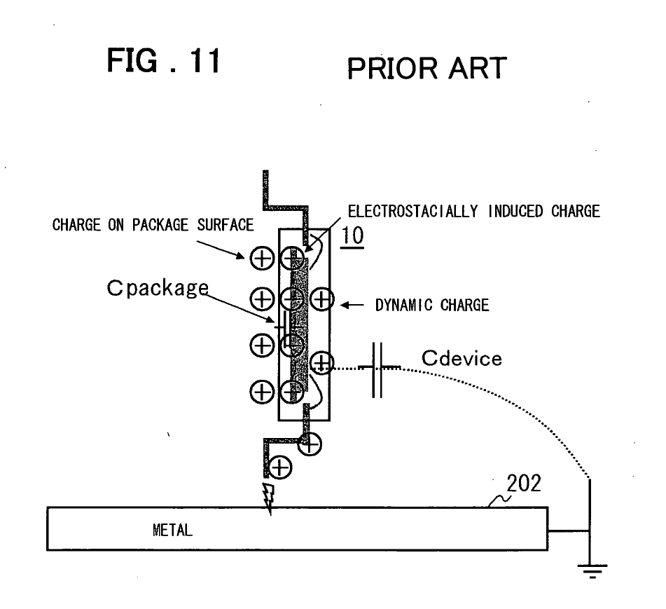

FIG. 12 is a diagram showing the configuration of a prior art direct charging CDM simulator.

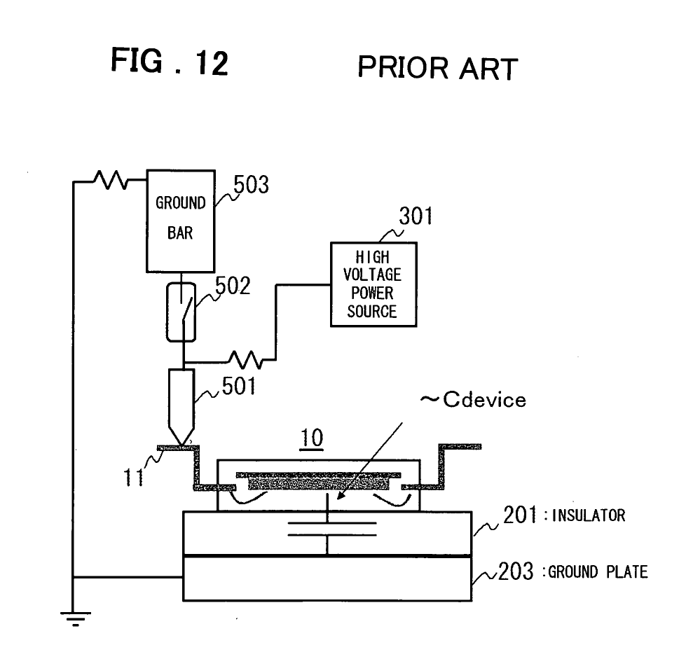

FIG. 13 is a diagram showing the configuration of a prior art FI-CDM simulator.

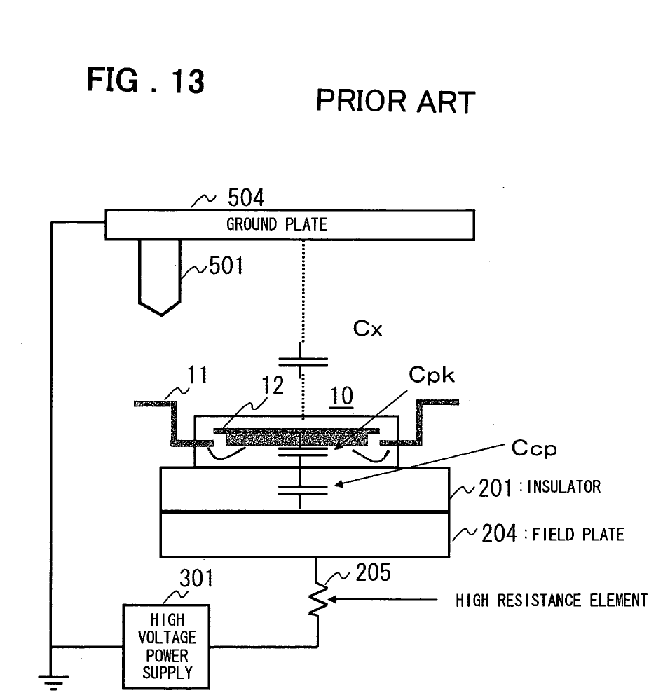

FIG. 14 is a diagram showing the configuration of a prior art relay FI-CDM simulator.

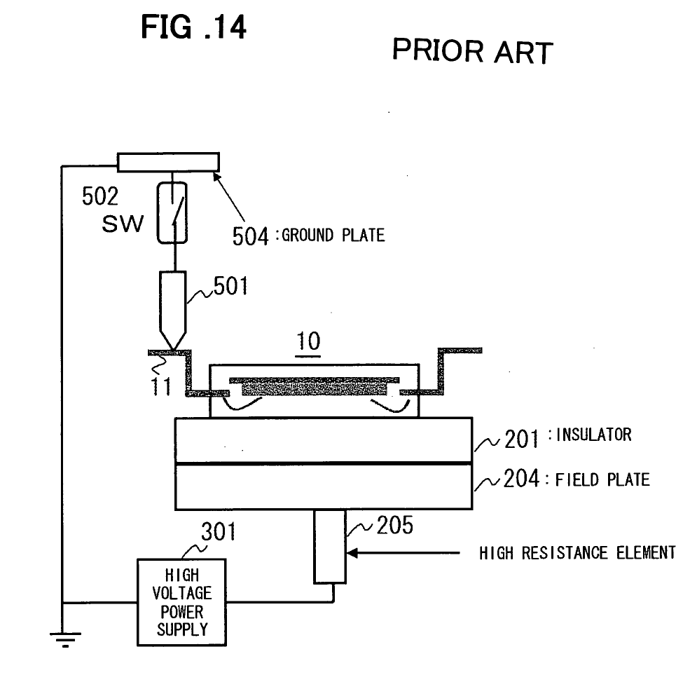

FIGS. 15A, 15B and 15C are views showing discharge current characteristics of simulators comprising field plates comprising metal, high resistive ceramics and electromagnetic wave absorbing sheet, respectively.

FIG. 16 is a diagram showing a current path in an IC and a circuit system in non-Patent Document 8.

FIG. 17 is a diagram showing a current path in an IC and a circuit system in present embodiment.

FIGS. 18A and 18B are views showing equivalent circuits of non-Patent Document 8 and present embodiment, respectively.

FIGS. 19A and 19B are views showing discharge currents when the area of the ground plate is small and large, respectively.

FIGS. 20A and 20B are views showing comparison between discharge current and JEDEC complying waveform when the area of the ground plate is large and small, respectively.

FIG. 21A is a diagram showing a combination of GND plate, field plate, and discharge current waveform. FIG. 21B is a diagram showing the configuration.

FIG. 22A is a diagram showing the section of a further embodiment of the present invention. FIG. 22B is an upper top view of FIG. 22A.

### PREFERRED EMBODIMENTS OF THE INVENTION

The present invention will now be described in more detail with reference to annexed drawings.

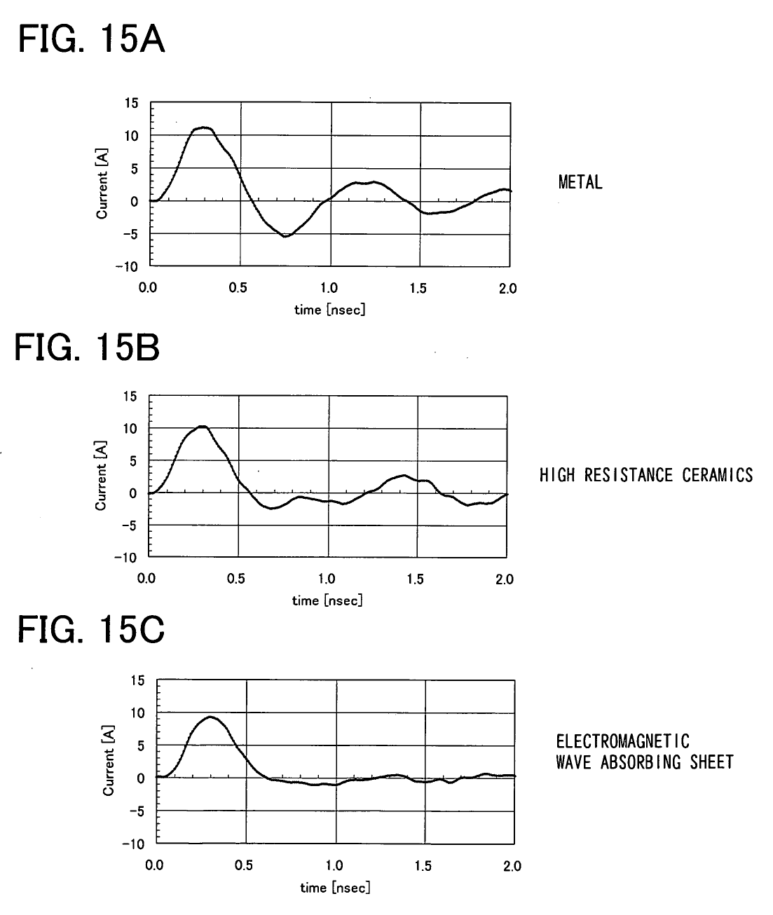

In existing CDM simulators, an electromagnetic wave are generated due to abrupt changes in potentials caused within an IC when electrostatic discharge occurs and are reflected on a lower metallic substrate, so that a capacitance coupling may occur between both electrodes. A device under test is usually spaced apart from the metallic surface in an FI-CDM model (refer to FIG. 15). In order to reproduce or simulate the electrostatic discharge phenomenon, a CDM simulator of the present invention comprises a plate, on which a device under test thereon is mounted, and which is made of a material for absorbing the an electromagnetic wave generated by CDM electrostatic discharge. The electromagnetic wave is thus absorbed through the plate and is not returned toward the device under test. In order to prevent capacitance coupling between a field plate and an electrode in the frequency band of electrostatic discharge, the field plate is made of a material which absorbs the an electromagnetic wave generated by the discharge.

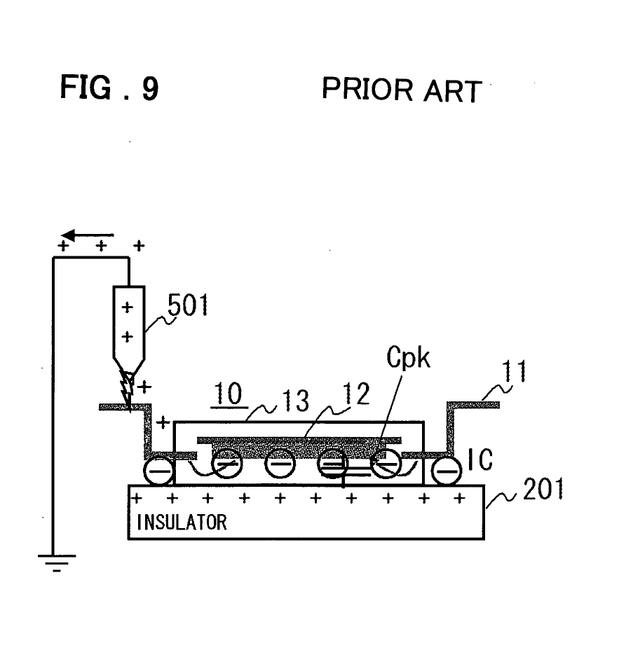

In FI-CDM model, it is necessary to apply a potential V to the field plate for the device under test for simulating the CDM discharge. In this case, a capacitance between a surface of an IC package facing to the plate for mounting the device under test and an internal conductor of an IC is Cpk (refer to FIG. 9). The amount of electrostatic charges (Q) is represented by an expression as follows:
Q=Cpk×V

where V is a voltage at the surface of the package and Cpk is a package capacitance.

In other words, this condition corresponds to that where an entire single surface is electrostatically charged to a potential V or the device under test is placed on a charged object.

Accordingly, it is preferable that the field plate has a resistance which is higher to some extent, if the field plate is to be made of a material having a higher resistance for absorbing the an electromagnetic wave generated by the discharge. Since discharging is successively conducted at intervals of 0.5 to 1 second across all terminals (pins), it is necessary to quickly supply a current from a voltage source so that the potential on an area of the field plate to which the sample is in contact with will become equal to that of an external power supply within this interval after the discharge. In this respect, the field plate is preferably lower in resistance. The field plate is designed so that its parameters such as structure and resistance will optimally meet these requirements.

The electromagnetic absorbing material may include various materials and composite materials, such as a material having a relatively higher surface resistive layer, which converts the an electromagnetic wave at the higher resistive area into heat for absorbing them, and a material which shifts the resonant frequency of the whole system toward the lower frequency side.

For example, a composite magnetic material in which metallic magnetic powders having a particle diameter in order of micron are dispersed in a resin may be used. It is said that a material having a high electric resistivity of about 10⁴ to 10⁷ο·cm is capable of absorbing an electromagnetic wave in the frequency range of 100 MHz to 5 GHz.

Engineering ceramics comprising electrically conductive ceramics powders therein which are uniformly dispersed in an insulating ceramics are able to have a higher electric resistivity of about 10⁴ to 10¹²ο·cm.

The CDM simulator may be represented by an equivalent circuit having a package capacitance added to a device capacitance and a capacitance which causes a high loss at frequencies higher than that of CDM discharge current.

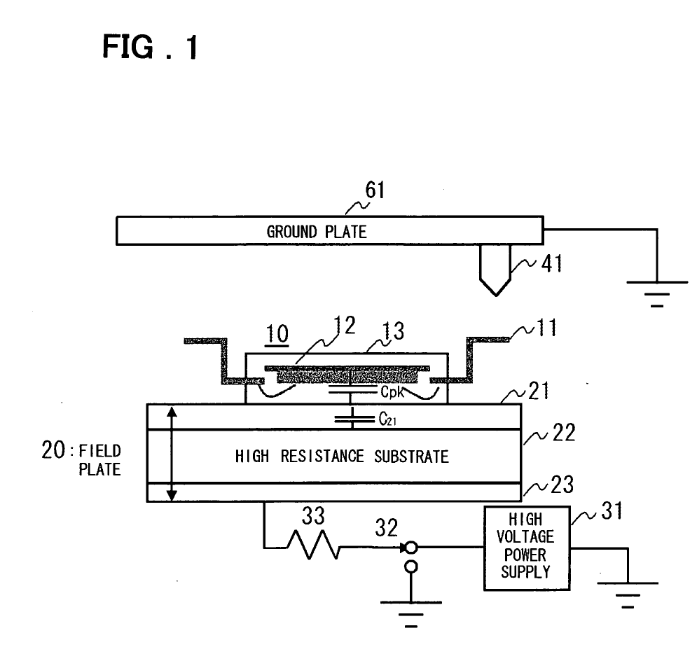

FIG. 1 is a diagram showing the configuration of a simulator according to a first embodiment of the present invention. Referring to FIG. 1, the simulator includes a filed plate 20 for electrostatically charging an IC 10 (a device under test) mounted thereon and a ground plate 61 for discharging the electrostatically charged IC 10. A probe needle 41 is provided in contact with the ground plate 61 but apart from a pin 11 of the IC 10 for performing the aerial discharge of the IC 10. An insulating film (substrate) 21 on which an IC 10 is mounted serves to prevent discharge which may occur when the space between the terminal and base substrate is narrow in case where the thickness of the package is thin, in a high voltage test. Accordingly, the insulating film 21 may be omitted in case where no discharge may occur for some packages.

If the insulating film 21 for the field plate 20 is necessary, the amount of the induced charges may be lowered since the capacitance of the field plate 20 is in-series connected to the package capacitance Cpk. An FR-4 substrate may be used in off-the-shelf CDM simulators, which may largely lower the amount of the discharged charges.

Although the material of the substrate is not particularly limited, Teflon™ has an advantage in that it has a dielectric loss which is constant at frequencies above GHz range and in that its capacitance value is independent of humidity, thereby making the design of CDM easier.

The material of the insulating film 21 requires to have only characteristics that the dielectric breakdown voltage between the IC and the field plate is kept higher to prevent direct discharge to the field plate and the capacitance is lower than that of the resin used for the IC to cause no reduction in effective applied voltage. For the substrate of Teflon™ having an electric insulation (relative dielectric constant of about 2), a configuration which makes the thickness of the substrate about 0.1 mm may be used.

A high resistance substrate 22 (also refereed to as “semi-conducting substrate” is disposed under the insulating film 21. The high resistance substrate 22 is made of a material which absorbs the an electromagnetic wave generated when the discharge of CDM occurs and has such a resistance that the field plate can be recharged by the field plate voltage supplied thereto and can be stabilized within one second.

Since the an electromagnetic wave which are generated by the discharge generally have frequencies above one GHz, absorption of the an electromagnetic wave occurs in relatively upper surface area of the high resistance substrate 22. Accordingly, the high resistance substrate 22 of the field plate 20 may be laminar-structure so that its resistivity is less at a depth sufficiently lower than the skin depth.

A metallic electrode 23 is disposed under the high resistance substrate 22 of the field plate 20. The electrode 23 can be switched to a connection with a high voltage source 31 or the frame ground for discharge via the high resistance element 33 by means of switch 32. When the resistance element 33 is switched to the high voltage source 31, a voltage is applied to the electrode 23 from the high voltage source 31.

In the present invention, the structure of the field plate is not limited to the structure of the foregoing embodiment. Other various variations may be made.

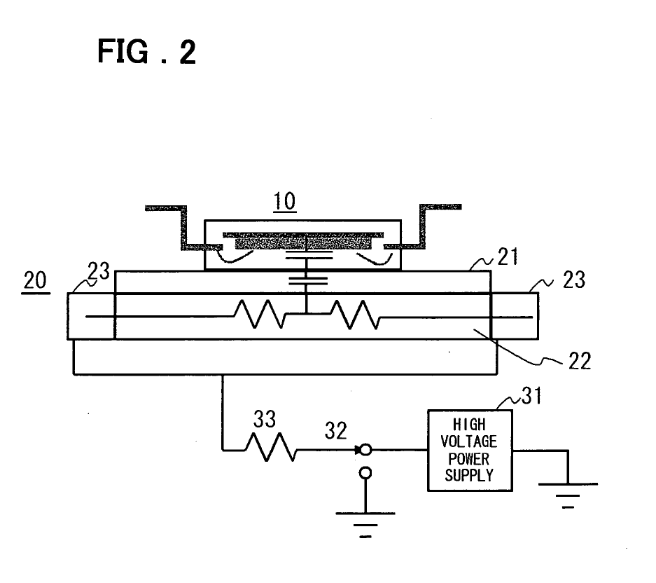

Referring now to FIG. 2, there is shown the structure of a variation of the field plate 20. The field plate 20 comprises an insulating film 21, a high resistance substrate 22 and a metallic electrode 23. Instead of disposing the metallic electrode 23 under the high resistance substrate 22 as shown in FIG. 1, a metallic electrode 23 may be disposed around the high resistance substrate 22 (surrounding the four sides of substrate), so that the electric potential is fixed.

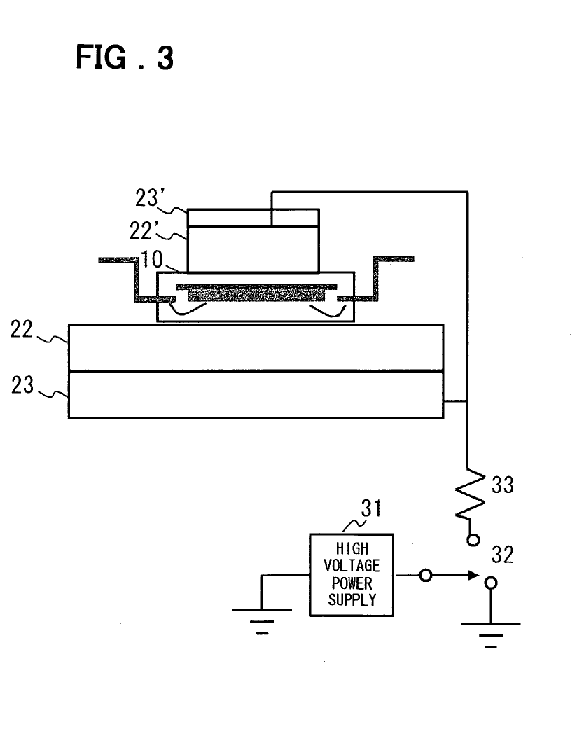

The configuration of another variation is shown in FIG. 3. Referring to FIG. 3, field plates (comprising a high resistance substrate 22 and metallic electrode 23) are disposed on both sides of the IC 10. In this configuration, the package capacitance Cpk can be maximized.

The IC 10 is placed on the field plate comprising the high resistance substrate 22 disposed on the metallic electrode 23 so that the face of the IC 10 faces thereto. A high resistance substrate 22′ and a metallic electrode 23′ are placed on the reverse side of the IC 10, so that the high resistance substrate 22′ faces thereto. A potential is applied to the both metallic electrode 23 and 23′.

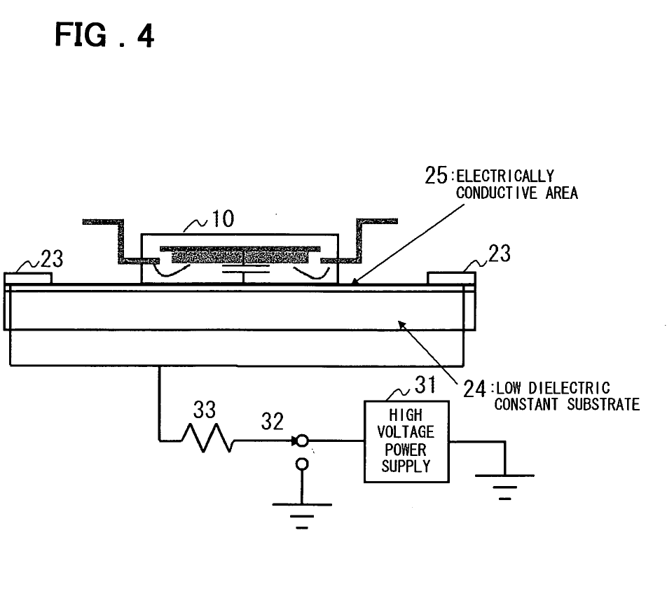

Referring to FIG. 4, a resistive layer (conductive area) 25 having a surface resistance of about 104 is provided on the surface of the insulating substrate (low dielectric constant substrate) 24 on which IC 10 is placed. The conductive area 25 is provided on the surface thereof with a metallic electrode 23 so that the electrode 23 surrounds IC 10. The metallic electrode 23 is connected to a high voltage source 31 via a resistor 33 and switch 32. A potential is fixed by applying a voltage from the high voltage source 31. The insulating substrate (low dielectric constant substrate) 24 is made of, for example, FR-4 . The conductive area 25 on the surface of the substrate 24 is made of a material to which an electrically conductive film is applied, a foamed styrol, the surface to which carbon black powders are kneaded to reduce the resistance of the surface layer, or a material made of a resin having a dielectric constant which is substantially equal to that of the package resin, the surface of which is provided with an electric conductivity.

Comparisons of results are shown in FIGS. 15A to 15C. FR-4 is usually used for the insulating substrate. Since physical parameters of FR-4 such as dielectric loss at high frequencies are not specifically defined, Teflon™ is used for comparison.

It is found from FIGS. 15A through 15C that an oscillation waveform is obtained when a metallic substrate is used and that over dumped waveforms are obtained so that the loss in the discharge circuit system is higher when high resistive ceramics and electromagnetic wave absorbing sheet are used.

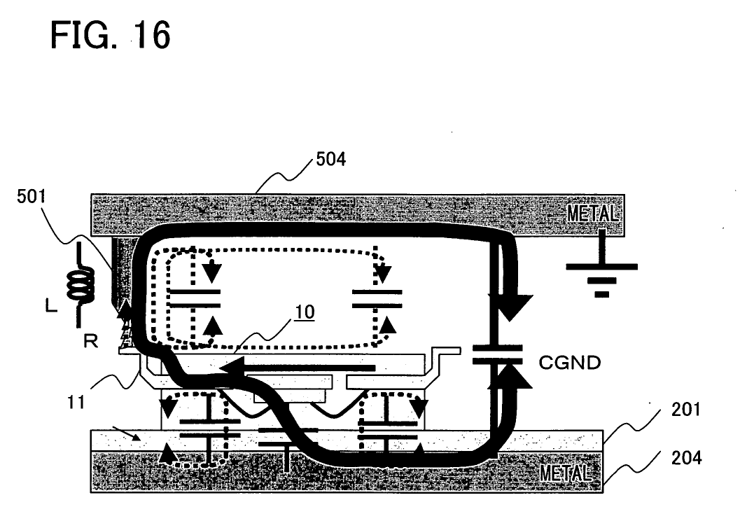

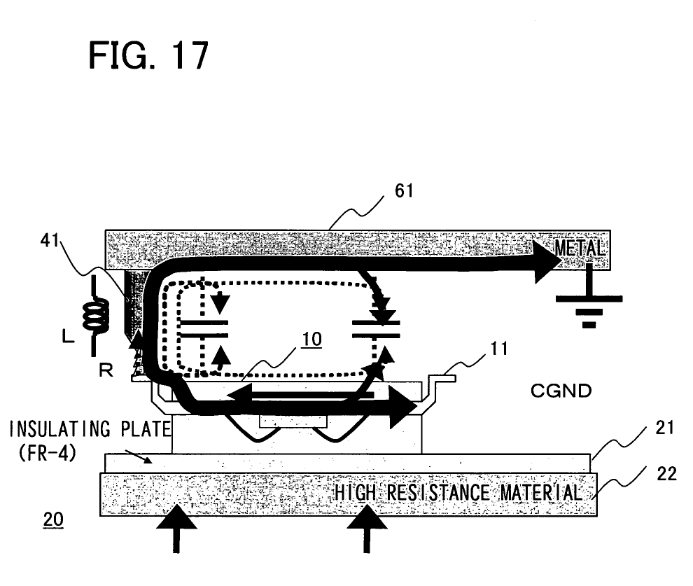

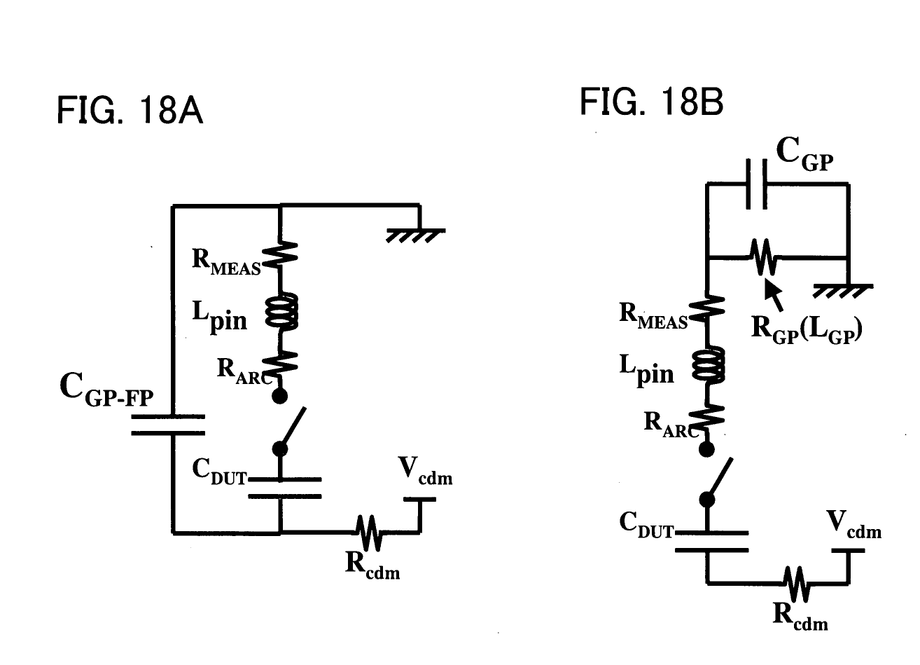

FIG. 16 shows a current path in the IC and circuit system of non-Patent Document 8. FIG. 17 shows a current path in the IC and circuit system in the present embodiment. An electromagnetic field is confined within a circuit comprising a capacitance between IC 10 and the field plate 204, a capacitance between IC 10 and a ground plate 504 and a capacitance between the field plate 204 and the ground plate 504 as shown in FIG. 18. Since a loss of system is caused by only a discharge resistor (more specifically, the plasma impedance of a discharge path and if an FR-4 substrate is used as insulator, its loss being included), a dumped oscillation is generated as shown in FIG. 17A. It is presumed that the current path mainly consists of a current path which is capacitance-coupled from the IC toward the field plate as shown in FIG. 16.

In the present embodiment, the dielectric loss between IC 10 and field plate 20 is large in the frequency range of CDM discharge current. This results in an over damping. It can be concluded that there is no current path extending to the field plate 20 as shown in FIG. 17 and in the discharge model, a case in which only insulting substrate 21 exists in the vicinity of IC 10 is reproduced. The present embodiment is able to the effect of reproducing or simulating the CDM discharge waveform in is worst case, in which the discharge wave form is subjected to an over-damping because the discharge current, if once flown out of the IC 10, does not return to the IC 10. More specifically, the inside of the IC 10 does not capacitance-couple with an external metal member in a frequency band of the CDM discharge current. Since the observed discharge waveform is actually over damped, it can concluded that the inside of the IC 10 does not capacitance-couple with the field-plate 20, thereby attaining the above effect.

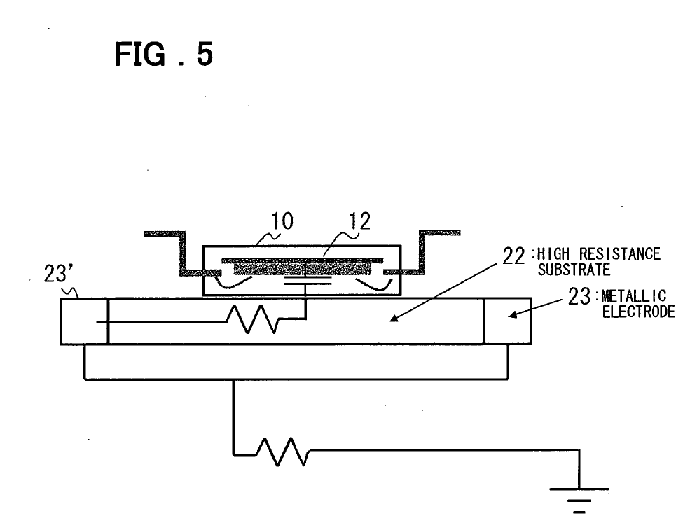

Another embodiment of the present invention will be described. The foregoing embodiment has been described with reference to FI-CDM. It is of course that the present invention is also applicable to D-CDM. FIG. 5 is a diagram showing the structure of a reference potential plate which is used for D-CDM. The reference potential plate comprises a high resistance substrate 22 on which an IC 10 is placed and electrodes 23 and 23′ which are disposed on the lateral side of the substrate 22. The electrodes 23 and 23′ are connected to the ground potential. When a voltage is applied to an internal conductor 12 within the package via a relay (not shown) from an external power supply (not shown), electrostatic charges are accumulated between the conductor 12 and the reference potential plate.

Now, a further embodiment of the present invention will be described. In the present embodiment, the potential on the field plate can be changed to a desired value.

Alternatively, separate electrodes (not shown) may be added to the upper portion of IC 10 so that they cover the whole of IC.

The present invention is also applicable to D-CDM test which is described non-Patent Document 4 and the like. In this case, a field plate is not used, but a metallic plate is used as a reference potential plate. Since the potential is connected to a reference potential via a resistance element, the present invention is applicable to the reference potential plate.

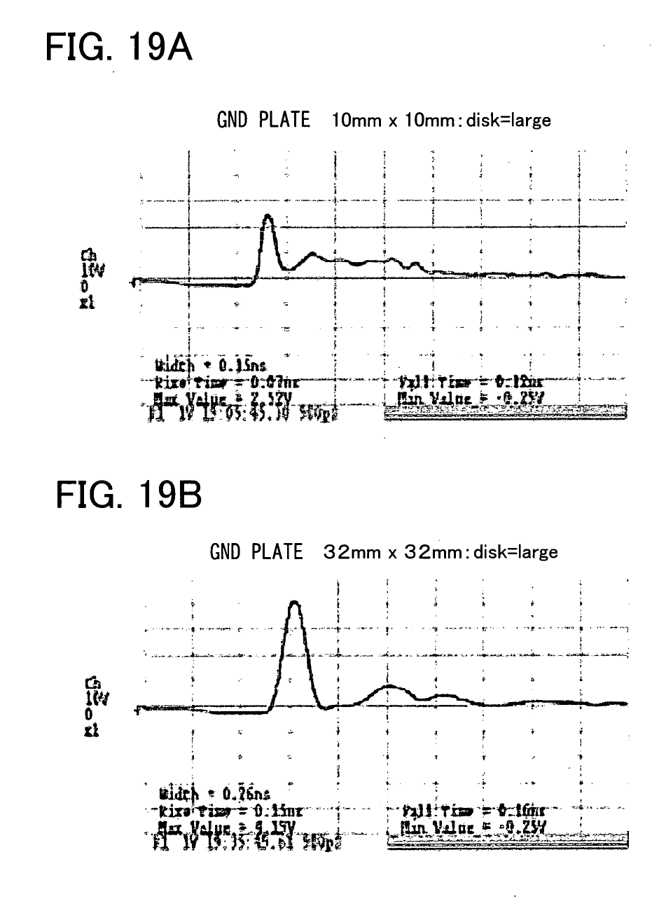

A further embodiment of the present invention will now be described. It is presumed that CDM simulator can be represented in an equivalent circuit as shown in FIG. 18A as is disclosed in, for example, non-Patent Document 8 for the purpose of estimating CDM test of products. However, it was confirmed from our experiments that discharge current changes when the configuration of the apparatus is changed to increase the peak value of the discharge current. Cases in which the size of a ground plate (in FI-CDM) is changed are shown in FIGS. 19A and 19B. It is found from the results shown in FIGS. 19A and 19B that when the area of the ground plate is small, a long continued tail portion becomes remarkable and correspondingly the peak value is lowered.

The equivalent circuit of the present invention is shown in FIG. 18B. The effect that electrostatic charges gradually flow to the frame ground due to the capacitance Cgp and the resistance of the ground plate is shown.

It is presumed that the parasitic inductance (Lpin in FIG. 18A or FIG. 18B) of the contact pogo-pin and the like is large for waveform complying normal JEDC standards, which will lower the peak value (rise time) of the discharge current.

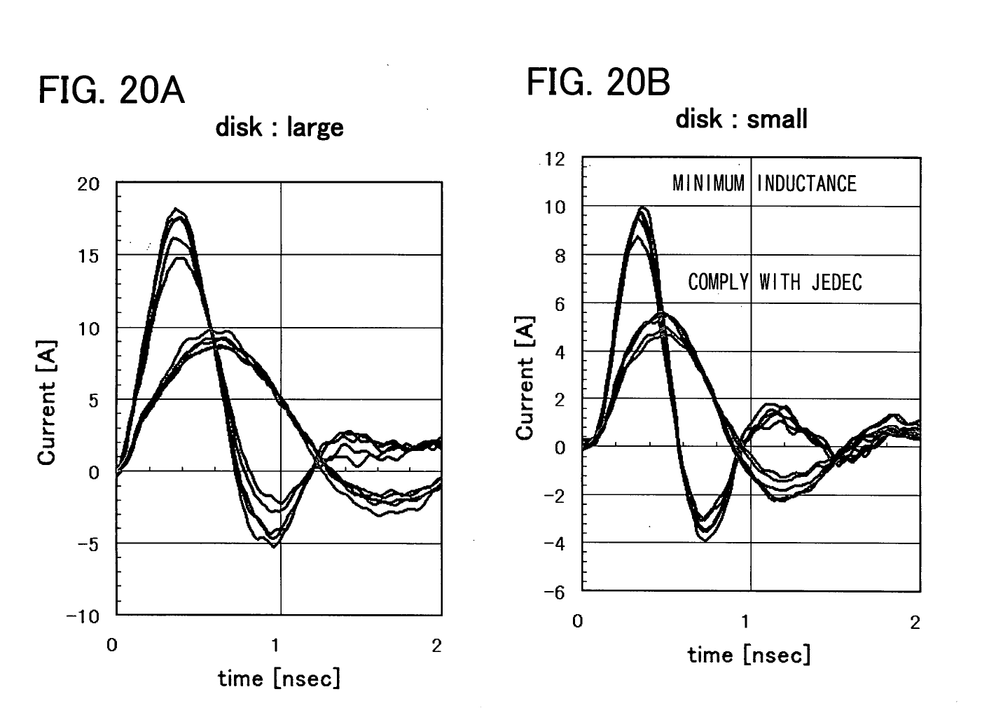

Therefore, the present embodiment is configured to suppress these parasiti. A result is shown for comparison in FIGS. 20A and 20B. FIGS. 20A and 20B show comparison of the discharge current when the area of the ground plate (or disk) is large and small with the current having waveform complying with JEDEC standards. The waveform of discharge current when the inductance is minimum is shown in FIG. 20B. It is found from FIGS. 20A and 20B that the peak value of the discharge current reaches about a double of the discharge current of waveform complying with JEDEC standards. Since an inductance in a packaged state is added in actual product and an impedance of a protective element is in-series added in an input/output buffer, an influence upon the waveform of the discharge current is mitigated.

It is confirmed that inductance is needed to be made large more than necessary for reproducing the discharge current waveform complying with JEDEC standards. Under these circumstances, the large inductance determines the waveform of the discharge current, the peak value of which is almost half of that of the present embodiment. In the present embodiment, for attaining the effect of reproducing the worst case discharge current, the ground plate is so adapted to exclude an inductance element to achieve the minimum value with regard to the rise time of the discharge current. The discharge waveforms shown in the Figures are those obtained using the CDM simulator which has the ground plate according to the present embodiment.

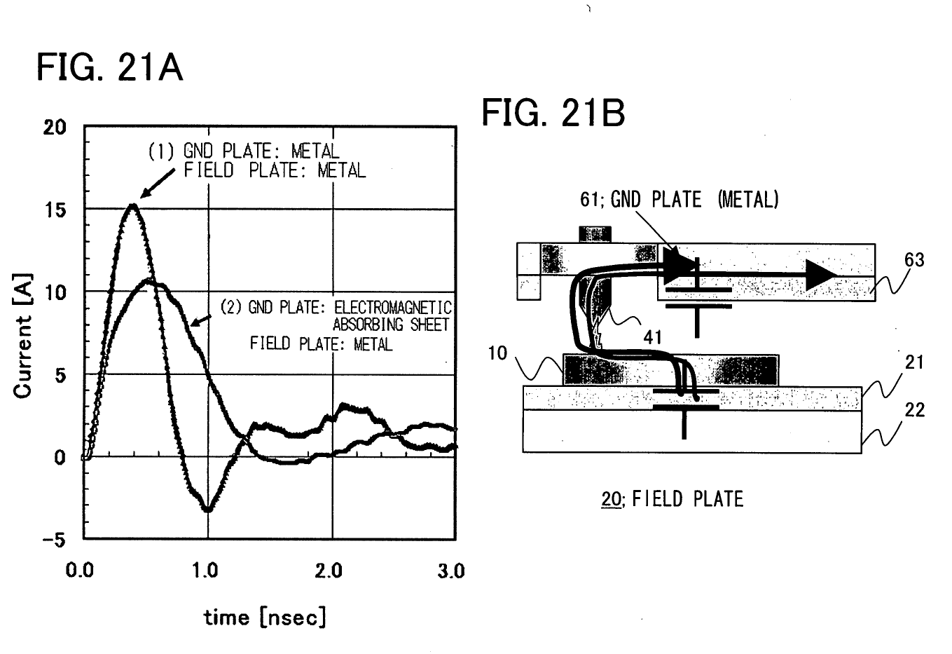

A resonance may occur in the waveform of the discharge current due to a resonance circuit including this capacitance under some conditions. Therefore, an electromagnetic wave absorbing sheet is disposed on a ground plate 61 (metal) in FIG. 21B. A comparison of the waveforms which are generated when the electromagnetic wave absorbing sheet is used and is not used is shown in FIG. 21A. In FIG. 21A, a graph (1) shows the transient characteristic of a discharge current when the ground plate 61 is made of a metal and the field plate 20 is made of a metal, while a graph shows the transient characteristics when the electromagnetic wave absorbing sheet 63 is disposed upon the ground plate 61 and the field plate 20 is made of a metal. The electromagnetic wave absorbing sheet 63 has a high surface resistance. Thus, the current is difficult to spread into the ground plate 61 as shown in FIG. 21B.

It is found that the electromagnetic wave absorbing sheet 63 disposed on the ground plate 61 provides substantially same effect as that provided by attaching the absorbing sheet on the side of the field plate 20. However, the rise time of the discharge current in case in which the absorbing sheet is disposed on the ground plate 61 is longer than that in case in which the absorbing sheet is mounted on the field plate 20.

This is due to the fact that the current spreads in a lateral direction (in a planar direction of the ground plate 61) so that the impedance of the current path on the side of the ground plate 61 increases while the potential of the ground plate 61 increases.

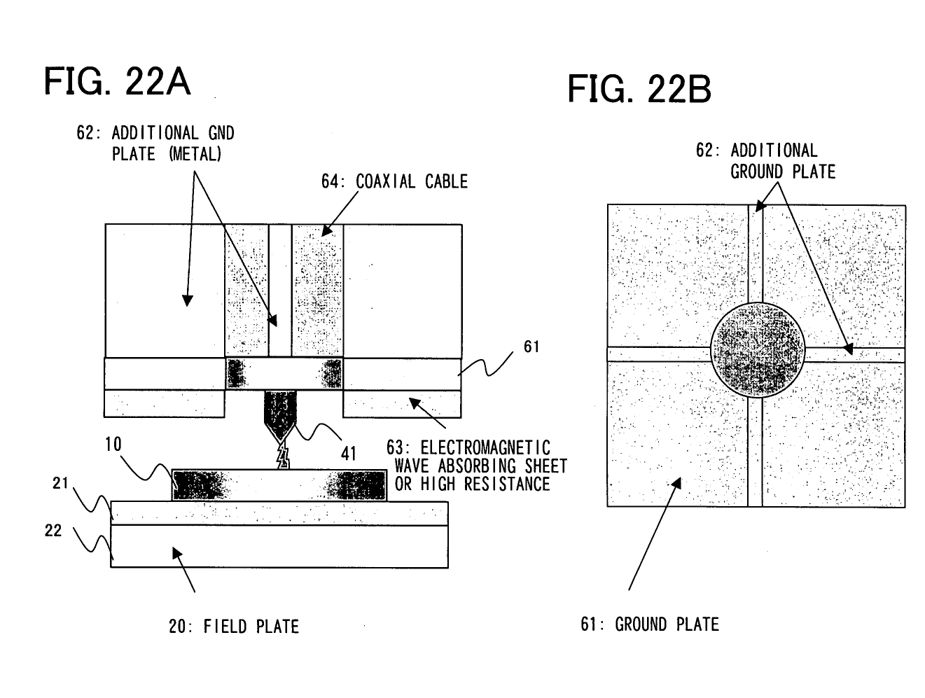

In order to prevent this, the present embodiment adopts a structure having a ground plate, the section and top of which are shown in FIGS. 22A and 22B, respectively. Additional ground plates extending in a vertical direction are disposed on the side of the ground plate 61 opposite to the IC. An electromagnetic wave absorbing sheet (which absorbs the an electromagnetic wave generated by the discharge) or high resistance substrate 63 is disposed on the side of the ground plate which faces the IC 10. A large capacitance of the ground plate 21 and fast rise time of the current can be achieved by providing the additional ground plates 62 on the ground plate 61. It is of course that the additional ground plates 62 are removable or additional. Although the ground plates 61 are square in shape in the embodiment, they may be in any shape, such as disc shape.

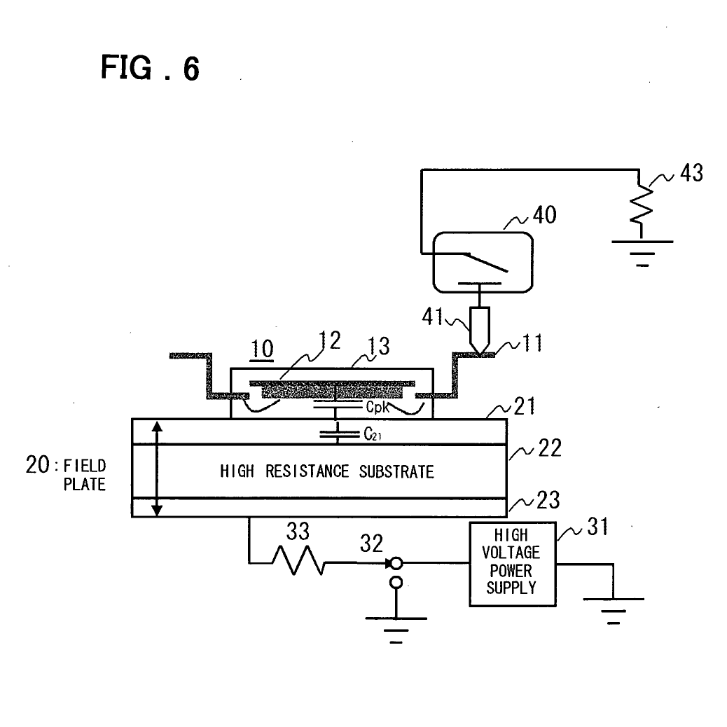

Referring to FIG. 6, a modification of the simulator shown in FIG. 1 will now be described. The filed plate 20 is the same as one shown in FIG. 1. The configuration of the simulator on the discharge side is such that discharge is caused via a switch 40 by bringing a contact needle (probe electrode) 41 into direct contact with a pin 11 of the IC 10. The switch 40 is not a conventional axial electrode, but a relay switch 40 having an electrode disposed in three directions in order to achieve a low inductance.

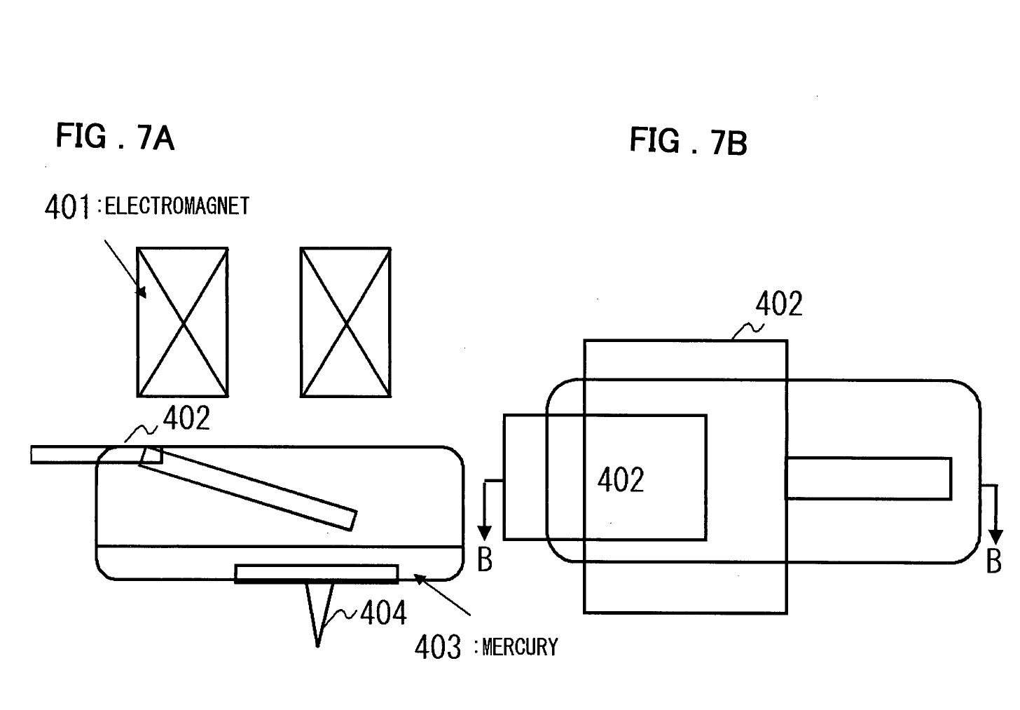

FIG. 7A is a sectional view showing the section of the switch 40 taken along line B-B in FIG. 7B. FIG. 7B is a top view showing the switch 40. An upper electrode 402 is of two-dimensional structure and leads out in three-directions. Reduction in inductance of the electrode makes the adjustment of the waveform of the discharge current easier. The switch 40 may be a mercury contact or vacuum relay.

The resistance value of the discharge path depends upon the shape of the contact needle 41, interval among discharges and contact speed, and often depends upon the potential difference. Accordingly, the simulator may be configured so that the resistance is changed depending upon the applied voltage. The simulator may be adjusted with detailed experiments, so that waveform at highest speed which may occur under the assembly environment of ICs can be simulated.

Although the present invention has been described with reference to foregoing embodiments, it is to be understood that various modifications, alternations and changes may be made by those skilled in the art without departure from the spirit and scope of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A field plate used in an electrostatic discharge test for electrostatically charging a device under test, said field plate comprising a member for absorbing an electromagnetic wave which is generated when discharge from said device under test occurs.

2. The field plate according to claim 1, comprising a first substrate of semi-conductivity as said absorbing member.

3. The field plate according to claim 2, wherein said first substrate has such a resistance value that the first substrate absorbs an induced current from said field plate at the time of said discharge.

4. The field plate according to claim 2, further comprising a second substrate having a predetermined dielectric constant disposed on said first substrate on the side on which said device under test is mounted.

5. The field plate according to claim 2, wherein said first substrate has a laminar structure comprising a plurality of layers having different resistivities.

6. The field plate according to claim 4, wherein said second substrate has a capacitance which is greater than a package capacitance of said device under test.

7. The field plate according to claim 4, further comprising an electrode disposed on said first substrate opposite to the side on which said second substrate is provided.

8. The field plate according to claim 1, comprising a first insulating substrate as said member;
an electrically conductive member disposed on the side of said first substrate on which said device under test is mounted, and
an electrode electrically connected to said electrically conductive member.

9. A simulator apparatus for electrostatic discharge test of a device under test, said apparatus comprising the field plate as set fourth in claim 1.

10. A simulator apparatus for electrostatic discharge test of a device under test, said apparatus comprising a member for absorbing an electromagnetic wave which is generated when discharge from said device under test occurs.

11. A simulator apparatus for electrostatic discharge test of a device under test, said apparatus comprising a power supply from which a voltage, not capacitance-coupling with an external environment in a discharge frequency band, is applied, when discharge from said device under test occurs.

12. A reference potential plate used in an electrostatic discharge test for supplying a device under test with a reference potential, said reference potential plate comprising a member for absorbing an electromagnetic wave which is generated when discharge from said device under test occurs.

13. A simulator apparatus for electrostatic discharge test of a device under test, said apparatus comprising a reference potential plate for supporting said device under test and for connecting said device under test to a reference potential, said reference potential plate comprising a substrate of semi-conductivity.

14. A ground plate used in an electrostatic discharge test for discharging a device under test, said ground plate comprising a relatively high resistance member.

15. A ground plate used in an electrostatic discharge test for discharging a device under test, said ground plate comprising a member for adding capacitance thereof.

16. The ground plate according to claim 15, wherein said member for adding capacitance comprises an additional ground plate disposed on the surface of said ground plate opposite to the surface facing to said device under test.

17. The ground plate according to claim 14, comprising a member for absorbing an electromagnetic wave which is generated when discharge from said device under test occurs.

18. The ground plate according to claim 14, comprising said relatively high resistance member on the surface of said ground plate facing to said device under test.

19. A simulator apparatus for electrostatic discharge test of a device under test, said apparatus comprising a ground plate as set fourth in claim 14.

20. A simulator apparatus for electrostatic discharge test of a device under test, said apparatus comprising:
a field plate used in an electrostatic discharge test for electrostatically charging a device under test; and
a ground plate for discharging said electrostatically charged device under test;
said field plate and/or said ground plate including a relatively high resistance member.

21. The simulator apparatus according to claim 20, wherein said ground plate comprises a member for adding capacitance thereof.

22. The simulator apparatus according to claim 21, wherein said member for adding capacitance comprises an additional ground plate on the surface of said ground plate opposite to the surface facing to said device under test.

23. The simulator apparatus according to claim 20, further comprising a member for absorbing an electromagnetic wave which is generated when discharge from said device under test occurs.

24. The simulator apparatus according to claim 20, further comprising a relatively high resistance member on the side of said ground plate facing to said device under test.

25. A method of carrying out an electrostatic discharge test of a device under test, said method comprising:
electrostatically charging the device under test using a field plate; and
discharging said electrostatically charged device under test using a ground plate;
wherein a relatively high resistance member is used as the field plate and/or the ground plate.

26. The method according to claim 25, wherein said ground plate is adapted to be further added with a capacitance.

27. The method according to claim 25, wherein an electromagnetic wave which is generated when discharge from said device under test occurs, is absorbed by an electromagnetic wave absorbing member provided on said ground plate and/or said field plate.
